(19) United States
(12) Patent Application Publication
(10) Pub. No.: US 2004/0201408 A1
(43) Pub. Date: Oct. 14, 2004

(54) Delay locked loop and a method for delay control

(75) Inventors: Martin Brox, Munchen (DE); Alessandro Minzoni, Morrisville, NC (US)

Correspondence Address: Maginot, Moore & Beck, Bank One Tower, Suite 3000, 111 Monument Circle, Indianapolis, IN, 46204, US

(73) Assignee: Infineon Technologies AG, Munchen (DE)

(21) Appl. No.: 10/748,711

(22) Filed: Dec. 30, 2003

(30) Foreign Application Priority Data
Dec. 30, 2002 (DE) 10261409.1-35

(51) Int. Cl. H03H 11/26

(52) U.S. Cl. 327/261

(57) ABSTRACT

The invention creates a delay control apparatus for provision of clock signals in circuit units having a delay device (100) comprising a first delay element (101) for provision of a variable time delay (105) between an output signal (104) and an input signal (103) for the first delay element (101), a feedback device (106) for feeding back the output signal (104) and a phase difference detection device (108) for detection of a phase difference between the input signal (103) and the fed-back output signal (107). The phase difference detection device emits a control signal (109) for controlling the first delay element (101) as a function of the detected phase difference, while a further, second delay element (102) which is connected in series with the first delay element (101), produces an additional delay as a function of a frequency of the output signal (103) which is detected by a frequency detection unit (110).

The present invention relates in general to a method and an apparatus for the provision of clock signals in circuit units, and relates in particular to a method and an apparatus for delay control of clock signals within circuit units, which are related in time to an external clock signal.

The increasing packing densities and physical sizes of integrated circuits are creating a need to provide a clock signal distribution and a clock signal delay extremely precisely on the chip—“on-chip”. Phase locked loops (PLLs) and delay locked loops (DLLs) are used for adjustable timing with respect to the clock signals that are used.

Conventionally, delay locked loops (DLLs) such as those described in the publication www.xilinx.com dated 5 Jul. 2002, are preferred for delay compensation and clock conditioning. Phase locked loops provide a propagation delay from zero for a very small clock shift between output clock signals which have to be distributed in a circuit unit.

A conventional delay locked loop for an SDRAM using digital components is described, for example, in the publication “IEEE, Journal of Solid-State Circuits, Vol. 32, pages 1728-1997, November 1997”.

Delay locked loops and phase locked loops based on self-biased techniques are described in the publication “IEEE, Journal of Solid-State Circuits, Vol. 31, pages 1723-1732, November 1996”.

One major disadvantage of known delay locked loops is that the delay locked loop is essentially a delay line which has to internally interpolate the external clock, which means that it must be able to match itself to input signals at all the possible frequencies. This means a time delay in a delay line must be longer than one clock cycle at the lowest frequency.

A further disadvantageous feature is that high resolution is required towards the higher frequencies, in order to achieve good data matching. The use of the same delay locked loop to cover low and high frequencies means that the delay line has to include a very large number of delay elements. If, by way of example, a delay time resolution of 20 pikoseconds (ps) is required, and the delay line is required to have an overall delay of 20 nanoseconds, then a total of N=20 ns/25 ps=800 individual elements are required in series. Such a large number of delay elements results in further problems, such as large circuit designs and excessive power consumption. Further problems then result with the signal timing and the circuit design for a structure with a large number of elements.

One object of the present invention is therefore to provide a delay locked loop which can be used equally well for low and high frequencies and which has a simple circuit design.

According to the invention, this object is achieved by a delay control apparatus having the features of patent claim 1. The object is also achieved by a method as specified in patent claim 8.

Further refinements of the invention can be found in the dependent claims. One major idea of the invention is to obtain prior knowledge of the frequency range in which an input signal that is to be delayed is located. Knowledge such as this allows a delay time to be set approximately, while the fine adjustment can conventionally be carried out by means of a delay locked loop.

The essence of the invention is to provide an additional frequency detection unit which acts on a delay time of a second delay element, which is connected in series with the conventional delay element. This allows flexible delay time control to be achieved equally well for low and high frequencies, with a simple circuit design.

The delay control apparatus according to the invention for provision of clock signals in circuit units, in which the clock signals within the circuit units can be predetermined variably in time with respect to an external clock signal, essentially has:

a) a delay device comprising a first delay element for provision of a variable time delay between an output signal and an input signal for the first delay element;

b) a feedback device to which the output signal is supplied, for feeding back the output signal, in which the feedback device emits a time-delayed, fed-back output signal; and

c) a phase difference detection device, for detection of a phase difference between the input signal and the fed-back output signal, in which the phase difference detection device emits a control signal for controlling the delay element as a function of the detected phase difference, in which the delay control apparatus also has at least one second delay element which is connected in series with the first delay element, and a frequency detection unit for detection of the frequency of the input signal, in which the second delay element can be adjusted as a function of the detected frequency of the input signal.

Advantageous developments and improvements of the respective subject matter of the invention can be found in the dependent claims. According to one preferred development of the invention, the delay control apparatus has a filtering device for filtering the control signal which is emitted from the phase difference detection device.

According to yet another preferred development of the present invention, the feedback device has a time delay which corresponds to the sum of a receiver time delay that is caused in the receiver and a driver time delay that is caused in the driver (OCD, Off Chip Driver), that is to say sum=Trcv+Tocd.

According to yet another preferred development of the present invention, a second delay element for low frequencies of the input signal, and at least one further second delay element for high frequencies of the input signal, are provided in the delay device. The same delay device can advantageously be used for high and low frequencies, just be switching over the second delay element.

According to yet another preferred development of the present invention, the delay device is formed by at least one capacitor element which is varied by means of a control voltage.

According to yet another preferred development of the present invention, the delay device is formed by at least one current inverter which is varied by means of a control voltage. According to yet another preferred development, the delay device is formed by an inverter chain.

Furthermore, the method according to the invention for provision of clock signals in circuit units in which the clock signals within the circuit units are pre-determined variably in time with respect to an external clock signal, has the following steps:

a) provision of a variable time delay between an output signal and an input signal of a delay device with a first delay element;

b) feedback of the output signal by means of a feedback device to which the output signal is supplied, in which the feedback device emits a time-delayed, fed-back output signal, and

c) detection of a phase difference between the input signal and the fed-back output signal by means of a phase difference detection device to which the input signal and the fed-back output signal are supplied, in which the phase difference detection device emits a control signal for controlling the first delay element as a function of the detected phase difference, in which the frequency of the input signal is detected by means of a frequency detection unit, and in which at least one second delay element, which is connected in series with the first delay element, is adjusted as a function of the detected frequency of the input signal.

According to yet another preferred development of the present invention, in order to allow the frequency detection unit to adjust the time delay of the second delay element, the cycle time of the delay control apparatus is compared with a number, which can be pre-determined, of delay units for the second delay element. The number of delay units for the second delay element is expediently eight.

According to yet another preferred development of the present invention, the delay control apparatus is reset by means of a reset pulse before frequency detection by means of the frequency detection unit.

According to yet another preferred development of the present invention, an overlap area is provided between adjacent detection frequency ranges.

According to yet another preferred development of the present invention, the output signal is delayed by the sum of a receiver time delay and of a driver time delay for feeding back in the feedback device, to which the output signal is supplied.

According to yet another preferred development of the present invention, the control signal which is emitted from the phase difference detection device is filtered in a filtering device for the delay control apparatus.

Exemplary embodiments of the invention will be explained in more detail in the following description and are illustrated in the drawings, in which:

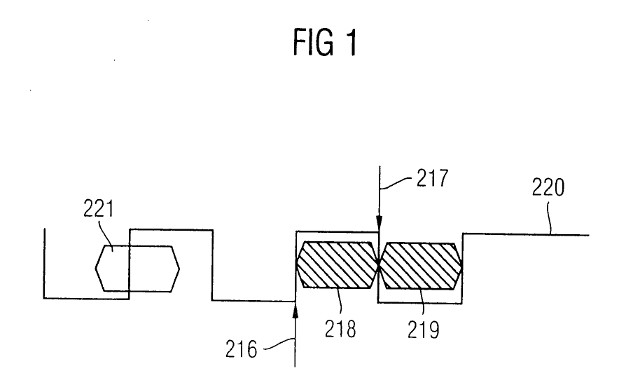

FIG. 1 shows an illustration of the reading/writing of data in a dynamic random access memory (DRAM) at twice the data rate (DDR, Double Data Rate);

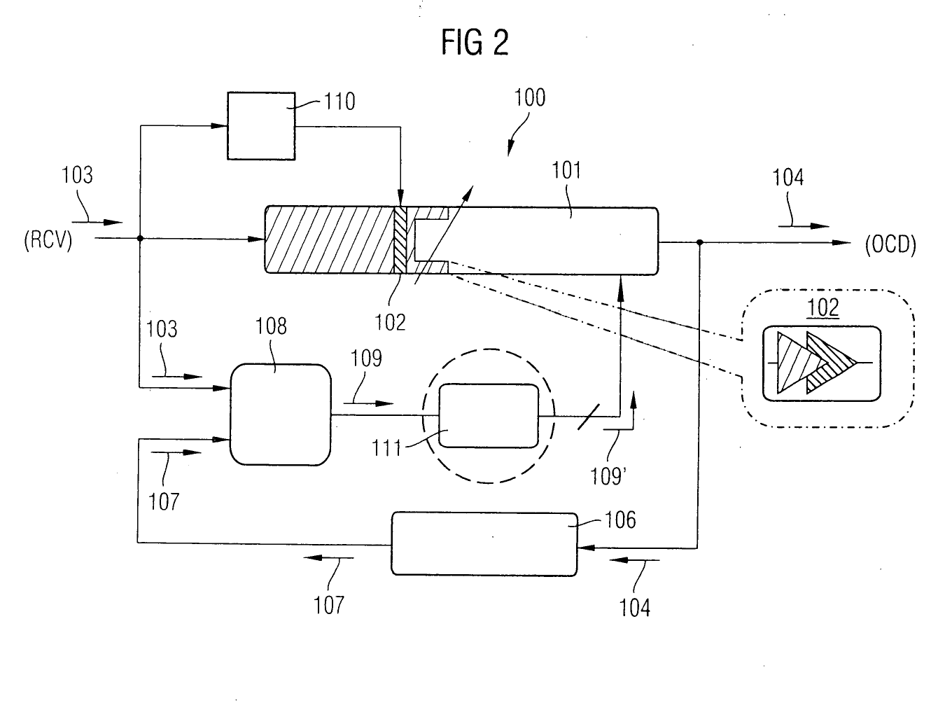

FIG. 2 shows a delay control apparatus with a frequency detection unit according to one preferred exemplary embodiment of the present invention;

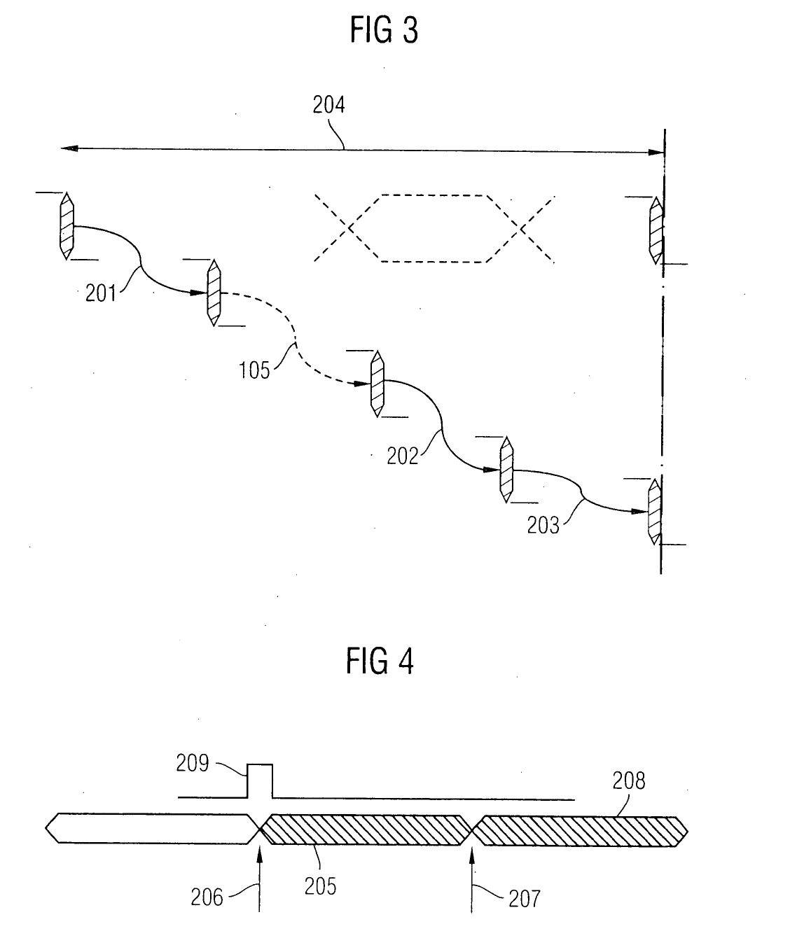

FIG. 3 shows a schematic illustration of the delay times which occur in the delay control apparatus, which is in the form of a delay locked loop;

FIG. 4 shows the timing diagram for a delay time control with upstream frequency detection;

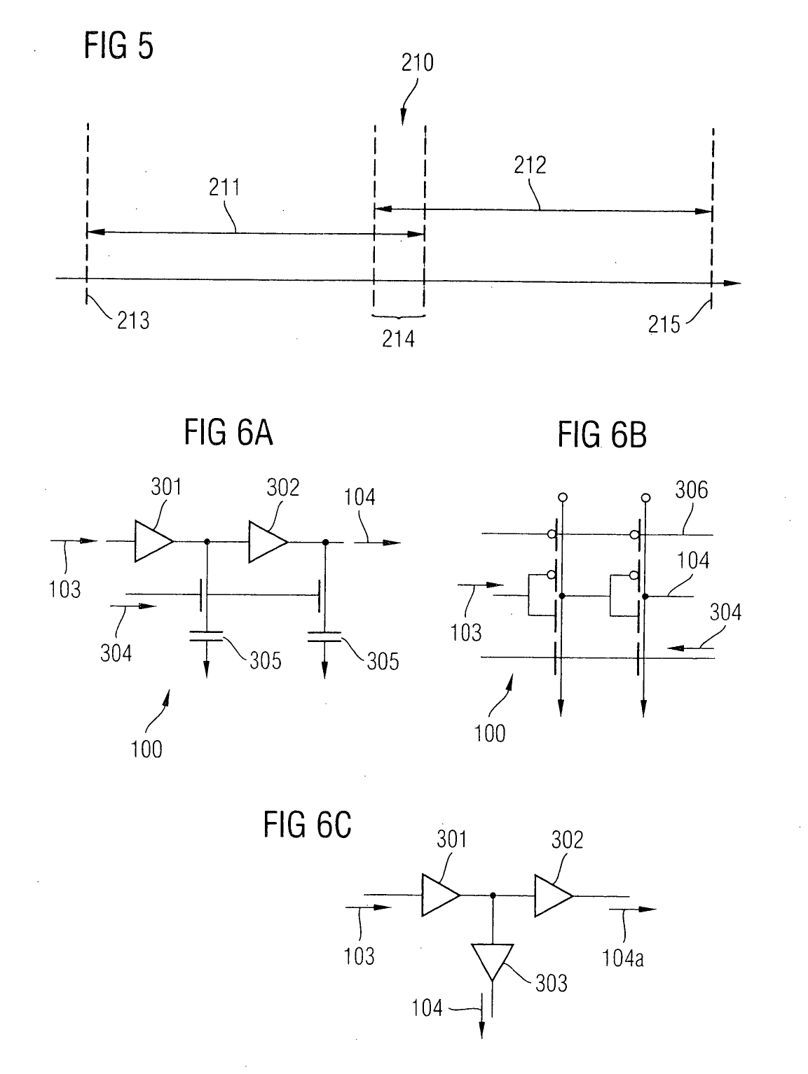

FIG. 5 shows an overlap area between a low detection frequency range and a high detection frequency range in the delay control apparatus;

FIG. 6(a) shows an example of a variable delay device based on a variable, voltage-dependent capacitor;

FIG. 6(b) shows an example of a delay device based on a current inverter which is varied by means of a control voltage;

FIG. 6(c) shows an example of a delay device based on an inverter chain;

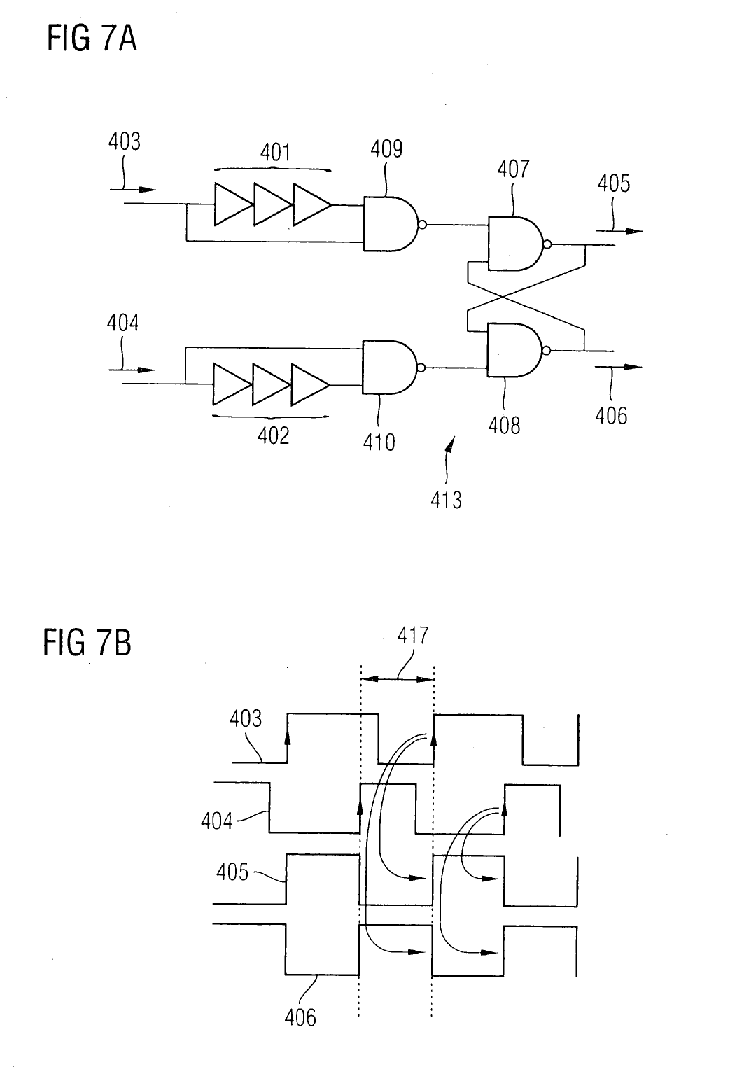

FIG. 7(a) shows an illustrative example of a frequency detection unit;

FIG. 7(b) shows a timing diagram of the clock signals which occur in the circuit diagram shown in FIG. 7(a);

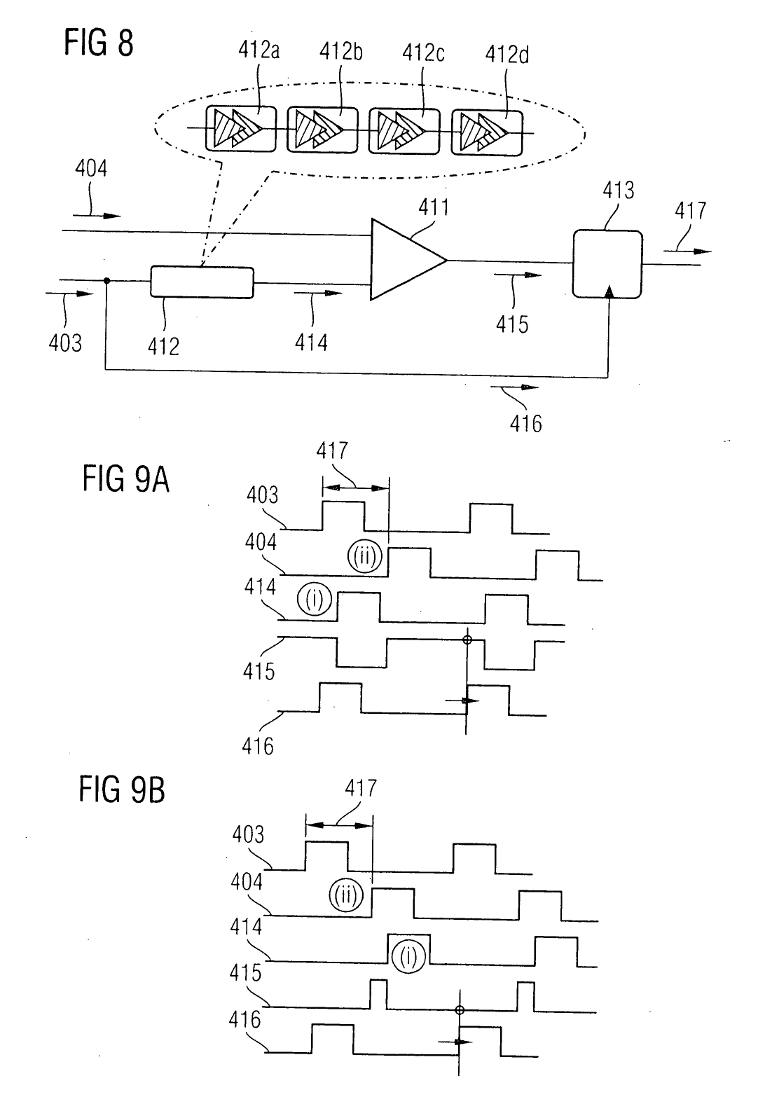

FIG. 8 shows a further example of a circuit arrangement for frequency detection;

FIG. 9(a) shows a flowchart for low input signal frequencies for the circuit arrangement shown in FIG. 7; and

FIG. 9(b) shows a flowchart for high input signal frequencies for the circuit arrangement shown in FIG. 7.

Identical reference symbols denote identical or functionally identical components or steps in the figures.

FIG. 1 shows the purpose of the method according to the invention and of the apparatus according to the invention on the basis of a delay locked loop for provision of clock data in a DRAM which is written to and read from at twice the data rate (DDR). Different clock flanks are predetermined as a function of a clock signal 220. In the DDR method, even-numbered DDR data 218 is addressed by means of an even-numbered DDR clock flank 216, while odd-numbered DDR data 219 is addressed by means of an odd-numbered clock flank 217. As can clearly be seen, these clock flanks must be positioned very precisely with respect to the data stream, and must not be in the form of an asynchronous data stream 221 as shown, by way of example, on the left in FIG. 1.

In order to provide flexible clock signal production for a DRAM memory and in order in particular to make it possible to operate in a wide frequency range from 50 MHz (20 ns) up to 500 MHz (2 ns), exact delay timing is required by means of a suitable delay control apparatus.

FIG. 2 shows a delay control apparatus according to one preferred exemplary embodiment of the present invention. This illustration shows an input signal 103 being input into the delay control apparatus and being received by a data stream receiver (RCV) which is not shown. After the processing in the delay control apparatus, the clock signal is provided as an output signal 104 from an external driver device (OCD, Off-Chip Driver, not shown), which is not arranged on the chip. The time delay for the input signal 103 is provided by means of a delay device 100, with the delay device 100 having a first delay element 101 and a second delay element 102.

The first delay element 101 is in the form of a variable delay element, whose delay time can be varied by means of a control signal 109 or a filtered control signal 109′. The delay time of the second delay element 102 can be adjusted in discrete steps, and produces an approximate time delay. The design of the delay locked loop and of the delay control apparatus will be described briefly in the following text. The output signal 104 is fed back via a feedback device 106. In the feedback device 106, the output signal 104 has applied to it, for example, a time delay which corresponds to the sum of a receiver time delay 201 and of a driver time delay 203, as will be explained in the following text with reference to FIG. 3.

A time-delayed, fed-back output signal 107 which is emitted from the feedback device 106 is supplied in the same way as the original input signal 103 to a phase difference detection device 108. The phase difference detection device 108 is used to detect the phase difference between the input signal 103 and the fed-back output signal 107, and to emit a control signal 109 which is dependent on the phase difference.

As is illustrated in the exemplary embodiment shown in FIG. 2, the control signal 109 is supplied to a filtering device 111, which emits the filtered control signal 109′. The filtered control signal 109′ varies the first delay element 101 until the phase difference between the input signal 103 and the fed-back output signal 107 is cancelled out. The overall delay time is governed by the delay time of the first delay element 101 and the delay time of the second delay element 102. The second delay element 102 is adjusted by means of an output signal from a frequency detection unit 110, that is to say a second delay time is set in the second delay element 102 as a function of the frequency of the input signal 103 as detected in the frequency detection unit 110. According to the invention, it is now expedient to provide different second delay elements 102 and different delay times for the second delay element 102 for different frequency ranges, as described in the following text with reference to FIG. 5.

As described in the following text with reference to FIG. 3, the overall delay time of the delay control apparatus is a function of the frequency of the input signal 103, so that in the event of a frequency change or in the event of a change to the frequency of the input signal 103, the overall delay time must be changed.

FIG. 3 shows, schematically, the composition of the overall delay time 204. The overall delay time is the sum of a receiver time delay 201, which occurs in the data stream receiver and is caused by the variable time delay 105 produced by the delay control device and a path time delay 202 which is caused by a data FIFO path, and a driver time delay 203 which is caused by the time delay to/in the Off-Chip-Driver. The overall time delay is thus given by the following formula:

T₂₀₁+T₁₀₅+T₂₀₂+T₂₀₃=N·T_{cycle(f)}.

The cycle time T_{cycle} is governed by the external clock, and a function of the frequency of the input signal 103; N is an integer, that is to say the cycle time T_{cycle} must correspond to a multiple of the overall time delay 204.

In accordance with the method according to the invention, frequency detection is now carried out by means of a frequency detection unit 110, before the operation of the delay locked loop starts.

In this case, it is not important to know the exact value of the frequency of the input signal 103 (see FIG. 2), but only the order of magnitude of the frequency of the input signal 103. There may be two or more of the second delay elements 102 as shown in FIG. 2, for example for a low frequency (long delay) and for a high frequency (short delay), in order to use the delay locked loop for a broad frequency range.

As is illustrated in FIG. 4, the frequency of the input signal 103 is checked before the start of operation of the delay locked loop. For this purpose, the delay control apparatus is first of all reset by means of a reset pulse 209, in order to provide a frequency detection start 206. For example, eight delay units 205 correspond to eight clock cycles of the detected input signal. The delay control mode 208 starts at the end 207 of frequency detection. After each reset pulse 209, a new frequency detection process is carried out by means of the frequency detection unit 110.

As mentioned above, two different second delay elements 102 may, for example, be provided, in order to cover a low frequency range and a high frequency range, as is illustrated schematically in FIG. 5. Two different frequency detection ranges 211, 212 overlap in an overlap area 210, which occurs at an intermediate frequency 214. The first detection frequency range 211 thus occurs between a low frequency 213 and the intermediate frequency 214, while the second detection frequency range 212 occurs between the intermediate frequency 214 and the high frequency 215. The two frequency ranges are covered by two different second delay elements 102.

FIGS. 6(a) to 6(c) show different circuit arrangements for provision of a variable time delay. FIG. 6(a) shows a delay device 100, which is formed by two capacitor elements 305 which are driven by means of a control voltage 304. The capacitor elements are each connected between the junction points of individual inverter elements 301 and 302 and ground, with the inverter elements 301, 302 etc. forming an inverter chain. The application of the control voltage 304 results in the capacitor elements 305 having a variable capacitance and, in conjunction with the inverter chain comprising the inverter 301, 302 etc., providing a time delay for the output signal 104 with respect to the input signal 103.

FIG. 6(b) shows, schematically, a circuit arrangement for a current inverter, which is varied by means of a control voltage 304. The effect of the circuit arrangement shown in FIG. 6(b) is similar to that of the circuit arrangement shown in FIG. 6(a), with the output signal 104 being delayed in time with respect to the input signal 103 as a function of the control voltage 304. FIG. 6(c) shows a further variant of a time delay, which can be predetermined such that it is fixed, by means of an inverter chain, with different and differently delayed output signals 104 and 104a being obtained from an input signal 103 by combining inverter elements 301, 302 and 303.

FIGS. 7(a) and 7(b) show a circuit arrangement and a flowchart, which are required for frequency detection. A clock input signal 403 and an inverted clock input 404 are respectively supplied directly and via an inverter chain 401 or 402 to the two respective inputs of a NAND gate 409 or 410. The outputs of the two NAND gates are supplied to the two NAND gates 407 and 408 of a locking gate 413, which produces a clock output signal 405 and an inverted clock output signal 406. The operation of the circuit arrangement shown in FIG. 7(a) will be explained with reference to FIG. 7(b). The locking gate changes its logic state whenever positive flanks occur on the one hand in the clock input signal 403 and on the other hand in the inverted clock input signal 404. This results in a regular clock output signal 405 and a regular inverted clock output signal 406, with half the period duration corresponding to a flank difference time between the two clock input signals 403 and 404. A good estimate of the cycle time (T_{cycle}) is obtained in accordance with the following formula from a measurement of the flank difference time 417 (T₄₁₇):

T_{cycle}≈2·T₄₁₇.

On the basis of the above formula, the cycle time and hence the frequency of the input signal which is applied to the delay control apparatus are known. This can be used, as explained above with reference to FIG. 2, to adjust the second delay element 102.

FIG. 8 shows a further method for determination of the frequency of the input signal 103 in the frequency detection unit 110, in order to carry out the method according to the invention for adjustment of the delay control apparatus. A clock input signal 403 is supplied to a reference delay device 412 and, as a gate signal 416 is supplied to a locking gate 413. An inverted clock input signal 404 is supplied directly to a clock generator 411.

The clock generator is also supplied with the clock input signal 403, delayed in the reference delay device 412, as a delayed clock input signal 414. It should be mentioned that the reference delay device is formed from individual reference delay elements 412a, 412b, 412c and 412d, for example four such elements. This results in a similar way to the method described with reference to FIGS. 7(a), (b) in a clock generator output signal 415 which is supplied to the locking gate 413. The output signal from the locking gate 413 once again provides information about the flank difference time 417.

The following text considers two operating states in order to determine the flank difference time 417, as are shown in FIG. 9(a) for low frequencies and in FIG. 9(b) for high frequencies. For the low frequency (FIG. 9(a)), the delay between the rising flank of the clock input signal 403 and the rising flank of the inverted clock input signal 404 is greater than the fixed delay, as can be seen from the delayed clock input signal 414. The event (i) therefore occurs, that is to say the flank of the delayed clock input signal 414 rises before the event (ii), that is the say the rise in the clock flank of the inverted clock input signal 404.

This means that the clock spends longer than the fixed delay time at a high level and, in consequence, the clock period is two or more times the fixed delay.

At the high frequency (FIG. 9(b)), the event (i) occurs after the event (ii), so that the period is shorter than twice the fixed delay. This results in a clock generator output signal 415 in FIG. 8 being a signal which spends a long time period at a 1-level, as is desirable for low frequencies (FIG. 9(a)) while, as is shown in FIG. 9(b), the clock generator output signal 415 for high frequencies is a short pulse.

This means that the delay control apparatus sets a long time delay in its second delay element 102, for detection of low frequencies, while the delay control apparatus sets a short time delay in its second delay element 102 for high frequencies. This allows the delay locked loops to be matched in an advantageous manner to the broad frequency range of the input signal.

Although the present invention has been described above on the basis of preferred exemplary embodiments, it is not restricted to them but can be modified in many ways.

The invention is also not restricted to the cited application options.

1-14. (canceled)

15. A delay lock loop apparatus for use with an externally generated clock signal comprising:
a delay device comprising a first delay element and a second delay element, wherein the first delay element is configured to generate a first output responsive to a control signal and a first input, and wherein the second delay element is configured to generate the first input responsive to the externally generated clock signal and a set signal related to the frequency of the externally generated clock signal,
a feedback device operably connected to the first delay element and configured to generate a time delayed first output,
a phase difference detection device configured to generate signal responsive to the phase difference between the time delayed first output and the externally generated clock signal, and
a frequency detection unit configured to generate the set signal responsive to the frequency of the externally generated clock signal.

16. The apparatus of claim 15, wherein the first delay element is responsive to a filtered control signal, and wherein the apparatus further comprises,
a filtering device operably connected to the phase difference detection device and the first delay element.

17. The apparatus of claim 15, wherein the feedback device is farther configured to generate the time delayed first output determined based upon a receiver time delay and a driver time delay.

18. The apparatus of claim 15, wherein the second delay element is configured to generate the first input responsive to a first set signal related to a first external clock frequency, the device further comprising,
a third delay element configured to generate the first input responsive to a second set signal related to a second external clock frequency.

19. The apparatus of claim 15, wherein the delay device comprises a controllably variable capacitor element.

20. The apparatus of claim 15, wherein the delay device comprises a controllably variable current inverter.

21. The apparatus of claim 15, wherein the delay device comprises an inverter chain.

22. A method of providing clock signals to a circuit, the method comprising the steps of:
providing a delay control apparatus comprising a first variable delay element and at least one frequency variable delay element,
detecting the frequency of an external clock signal,
adjusting the time delay of the at least one frequency variable delay element based upon the frequency of the external clock signal,
delaying the external clock signal with the at least one frequency variable delay element and providing the delayed external clock signal to the first variable delay element,
further delaying the delayed external clock signal with the first variable delay element,
providing the further delayed external clock signal to a feedback device,
time delaying the further delayed external clock signal with the feedback device,
detecting the phase difference between the time delayed external clock signal and the external clock signal,
generating a control signal based upon the detected phase difference, and
controlling the time delay of the first variable delay element with the control signal so as to reduce the detected phase difference.

23. The method of claim 22, wherein the step of detecting the frequency of an external clock signal comprises the step of:
detecting the frequency of an external clock signal over a predetermined number of frequency cycles.

24. The method of claim 23, wherein the step of detecting the frequency of an external clock signal over a predetermined number of frequency cycles comprises the step of
detecting the frequency of an external clock signal over eight frequency cycles.

25. The method of claim 22, further comprising, before the step of detecting the frequency of an external clock signal, the step of:
resetting the delay control apparatus with a reset pulse.

26. The method of claim 22, wherein the step of providing at least one frequency variable delay element comprises the step of
providing a first frequency variable delay element responsive to control signals related to a first frequency and a second frequency and not responsive to control signals related to a third frequency, and
providing a second frequency variable delay element responsive to control signals related to the second frequency and the third frequency and not responsive to control signals related to the first frequency.

27. The method of claim 22, wherein the step of time delaying the further delayed external clock signal comprises the steps of,
providing a receiver and a driver,
determining the receiver time delay,
determining the driver time delay, and
time delaying the further delayed external clock signal by an amount of time equal to the receiver time delay plus the driver time delay.

28. The method of claim 22, further comprising the steps of;
providing a filtering device, and
filtering the generated control signal.
